(19) United States
(12) Patent Application Publication
(10) Pub. No.: US 2010/0078746 A1
(43) Pub. Date: Apr. 1, 2010

(54) SEMICONDUCTOR DEVICE AND METHOD OF MANUFACTURING THE SAME

(76) Inventor: Oh-Jin Jung, Bucheon-si (KR)

Correspondence Address: SHERR & VAUGHN, PLLC, 620 HERNDON PARKWAY, SUITE 320, HERNDON, VA, 20170, US

(21) Appl. No.: 12/568,820

(22) Filed: Sep. 29, 2009

(30) Foreign Application Priority Data
Oct. 1, 2008 (KR) 10-2008-0096409

(51) Int. Cl. H01L 31/0232; H01L 31/00; B05D 5/12; C23F 1/00; C23C 16/513

(52) U.S. Cl. 257/432; 257/461; 427/97.3; 216/13; 427/569; 438/70; 257/E31.001; 257/E31.127

(57) ABSTRACT

A semiconductor device, an image sensor, and methods of manufacturing the same. A semiconductor device may include metal interconnections formed over a lower substrate, a hard mask formed over metal interconnections, and/or an insulating layer formed over a surface of a lower substrate. A semiconductor device may include an insulating layer including an air gap formed between metal interconnections. An image sensor may include a pixel array area having photodiodes and transistors, and/or a logic area having a plurality of transistors, which may be formed over a semiconductor substrate. An image sensor may include a metal interconnection and/or an insulating layer structure connected to transistors, and may cover a pixel array area and/or a logic area. An image sensor may include a color filter layer formed over a pixel array area, and an insulating layer structure of a pixel array area having an air gap between metal interconnections.

The present application claims priority under 35 U.S.C. 119 to Korean Patent Application No. 10-2008-0096409 (filed on Oct. 1, 2008), which is hereby incorporated by reference in its entirety.

### BACKGROUND

Embodiments relate to electric devices and methods thereof. Some embodiments relate to a semiconductor device and a method of manufacturing the same, including an image sensor.

Image sensors may be semiconductor devices and may convert an optical image into an electric signal. An image sensor may be classified as a Charge Coupled Device (CCD). A CCD device may include individual Metal Oxide Silicon (MOS) capacitors which may be located closely to each other such that charge carriers may be stored in or discharged from the capacitors. An image sensor may be classified as a Complementary MOS (CMOS) image sensor. A CMOS may employ a switching scheme which may sequentially detect outputs by providing MOS transistors, corresponding to the number of pixels, through a CMOS technology which may use peripheral devices such as a control circuit and/or a signal processing circuit.

A CCD may require a relatively complicate driving scheme and/or may cause relatively large power consumption with a relatively large number of mask process steps. A signal processing circuit may not be realized in a CCD chip. To address the drawbacks of a CCD, use of a CMOS image sensor may be investigated. A CMOS image sensor may be relatively highly integrated while relatively lowering power consumption. A pixel of a CMOS image sensor may include a photodiode which may convert external light into electric signals, and may include at least one MOS transistor that may processes signal charges generated from a photodiode.

A CMOS image sensor may include multi-layer interconnections for forming pixels and/or peripheral circuits. Various types of insulating layers may be formed in and/or over a photodiode of a pixel of a CMOS image sensor. Some insulating layers formed in and/or over a photodiode may represent lower transmittance relative to external light. In addition, some insulating layers may absorb and/or reflect external light. Therefore, if such insulating layers are formed in and/or over a photodiode, quantum efficiency may be relatively lowered and/or light sensitivity of an image sensor may be degraded.

Thus, there is a need for a device and a method of manufacturing a device which may maximize relative light sensitivity of a photodiode. There is a need for a device and a method of manufacturing a device which may substantially prevent light transmittance from being substantially relatively lowered.

### SUMMARY

Embodiments relate to a semiconductor device and a method of manufacturing a semiconductor device. According to embodiments, a semiconductor device and a method of manufacturing the same may maximize relative light sensitivity of a photodiode. In embodiments, a semiconductor device and a method of manufacturing the same may maximize relative light sensitivity of a photodiode while substantially preventing light transmittance from being substantially relatively lowered. In embodiments, an air gap may be formed in and/or over an insulating layer formed in and/or over a photodiode.

Embodiments relate to a semiconductor device. According to embodiments, a semiconductor device may include metal interconnections formed in and/or over a lower substrate. In embodiments, a semiconductor device may include a hard mask formed in and/or over metal interconnections. In embodiments, a semiconductor device may include an insulating layer formed in and/or over a surface, which may be an entire surface, of a lower substrate including an air gap disposed between metal interconnections.

Embodiments relate to a method of manufacturing a semiconductor device. According to embodiments, a method of manufacturing a semiconductor device may include forming a metal layer in and/or over a lower substrate. In embodiments, a method of manufacturing a semiconductor device may include forming a mask layer in and/or over a metal layer and/or forming a hard mask, for example by patterning a mask layer. In embodiments, a method of manufacturing a semiconductor device may include forming a metal interconnection, for example by etching a metal layer using a hard mask.

According to embodiments, a method of manufacturing a semiconductor device may include forming a first insulating layer along a concave-convex section in and/or over a hard mask, and/or a metal interconnection. In embodiments, a method of manufacturing a semiconductor device may include forming a second insulating layer in and/or over a first insulating layer. An air gap may be formed, for example between metal interconnections in accordance with embodiments. In embodiments, a method of manufacturing a semiconductor device may include planarizing a second insulating layer.

Embodiments relate to a semiconductor device. According to embodiments, a semiconductor device may include a pixel array area and/or a logic area in and/or over a semiconductor substrate. In embodiments, a pixel array area may include photodiodes and/or transistors. In embodiments, a logic area may include a plurality of transistors.

According to embodiments, a semiconductor device may include a metal interconnection and/or an insulating layer structure which may be connected to transistors while covering at least one of a pixel array area and a logic area. In embodiments, a semiconductor device may include a color filter layer in and/or over a pixel array area. In embodiments, an insulating layer structure of a pixel array area may include an air gap, which may be formed between metal interconnections.

Embodiments relate to a method of manufacturing a semiconductor device. According to embodiments, a method of manufacturing a semiconductor device may include forming a pixel array area which may have a photodiode and/or a transistor. In embodiments, a method of manufacturing a semiconductor device may include forming a logic area which may have a plurality of transistors in and/or over a semiconductor substrate. In embodiments, a method of manufacturing a semiconductor device may include forming a pre-metal dielectric (PMD) layer in and/or over a surface, which may be an entire surface, of a semiconductor substrate. In embodiments, a pixel array area and/or a logic area may be covered with a PMD layer.

According to embodiments, a method of manufacturing a semiconductor device may include forming a metal interconnection connected to a transistor in and/or over a PMD layer. In embodiments, a method of manufacturing a semiconductor device may include forming an insulating layer structure including an air gap, which may be formed between metal interconnections corresponding to a photodiode. A color filter layer may be formed in and/or over a pixel array area in accordance with embodiments.

According to embodiments, an air gap may be formed in and/or over an insulating layer formed in and/or over a photodiode of an image sensor. In embodiments, transmission efficiency of light may be maximized which is incident into a photodiode from a micro-lens. In embodiments, light absorption and/or light reflection caused by an insulating layer may be substantially avoided. In embodiments, quantum efficiency may be relatively maximized and/or light sensitivity may be maximized.

### DRAWINGS

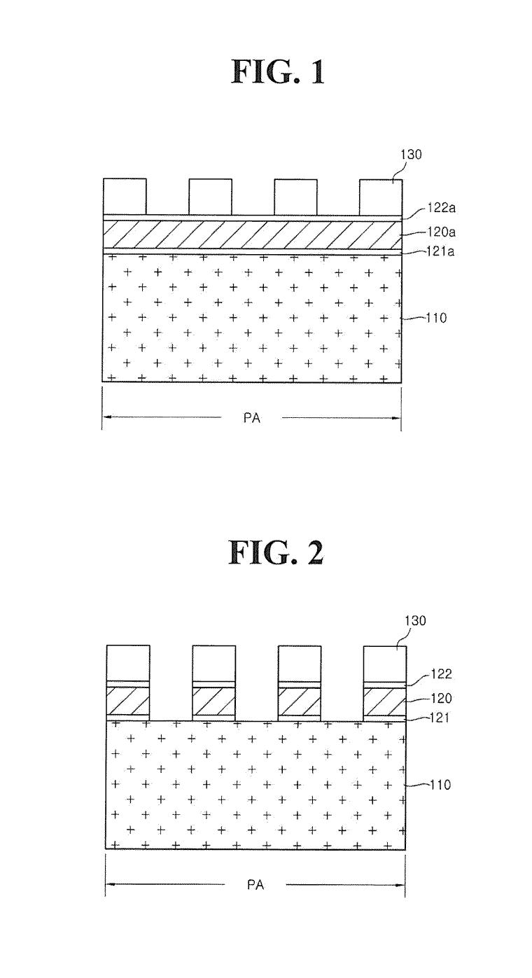

Example FIG. 1 to FIG. 5 illustrate cross sectional views of a method of manufacturing an image sensor in accordance with embodiments.

Example FIG. 6 illustrates a plan view of an image sensor in accordance with embodiments.

### DESCRIPTION

Embodiments relate to a method of manufacturing an image sensor. Example FIG. 1 to FIG. 5 illustrates cross sectional views of a method of manufacturing an image sensor in accordance with embodiments. Referring to FIG. 1, first barrier layer 121a, metal layer 120a, second barrier layer 122a, and/or mask pattern 130 may be formed in and/or over lower substrate 110. In embodiments, first barrier layer 121a, metal layer 120a, second barrier layer 122a, and/or mask pattern 130 may be sequentially formed in and/or over lower substrate 110. In embodiments, mask pattern 130 may serve as a hard mask.

According to embodiments, a mask layer, an anti-reflection layer and/or a photoresist layer may be formed in and/or over second barrier layer 122a, which may be sequentially formed. In embodiments, a photoresist layer may be selectively exposed and developed. In embodiments, an anti-reflection layer and/or a mask layer may be etched using a photoresist pattern as a mask, and may form a mask pattern, such as mask pattern 130. In embodiments, a remaining photoresist pattern and/or an anti-reflection layer pattern may be removed.

According to embodiments, lower substrate 110 may include a semiconductor substrate. In embodiments, lower substrate 110 may include a semiconductor substrate and/or a plurality of transistors formed in and/or over a semiconductor substrate. In embodiments, lower substrate 110 may include a semiconductor substrate, a plurality of transistors formed in and/or over a semiconductor substrate, and/or a pre-metal dielectric (PMD) layer formed in and/or over a semiconductor substrate covering one or more transistors. In embodiments, lower substrate 110 may include a semiconductor substrate, a photodiode area formed in and/or over a semiconductor substrate by for example ion implantation, a plurality of transistors, and/or a PMD layer formed in and/or over a semiconductor substrate covering one or more transistors.

According to embodiments, a PMD layer may include a SiO₂ layer. In embodiments, first barrier layer 121a and/or second barrier 122a may include at least one of Ta, TaN, TaAlN, TaSiN, Ti, TiN, WN, TiSiN, and TCu. In embodiments, first barrier layer 121a and/or second barrier layer 122a may include a single layer structure or a multi-layer structure using for example the above-identified elements and the like.

According to embodiments, first barrier layer 121a and/or second barrier layer 122a may maximize filling-up characteristics of metal layer 120a, which may be aluminum metal layer 120a. In embodiments, first barrier layer 121a and/or second barrier layer 122a may maximize reliability of an interconnection as a line width of an interconnection is relatively reduced. In embodiments, first barrier layer 121a and/or second barrier layers 122a may be deposited in and/or over a lower structure at a thickness between approximately 50 Å to 400 Å. In embodiments, deposition may occur through a sputtering scheme, for example using titanium as a target material and injecting argon (Ar) into a chamber at approximately and/or below a temperature of 200° C.

According to embodiments, metal layer 120a may include at least one of aluminum, copper, tungsten and aluminum alloy. In embodiments, metal layer 120a may be deposited in and/or over first barrier layer 121a at a thickness between approximately 300 Å to 500 Å. In embodiments, deposition may occur through a sputtering scheme, for example approximately at or above a temperature of 200° C. In embodiments, and substantially similar to first barrier layer 121a, second barrier layer 122a may be formed in and/or over metal layer 120a at a thickness between approximately 50 Å to 90 Å.

According to embodiments, mask pattern 130 may be used for etching metal layer 120a. In embodiments, mask pattern 130 may include a hard mask material. In embodiments, mask pattern 130 may include at least one of SiON and SiO₂. In embodiments, mask pattern 130 may include material and/or etching characteristics which are substantially similar as those of an insulating layer which may be formed below metal layer 120. In embodiments, mask pattern 130 may include a thickness between approximately 500 Å to 1200 Å.

Referring to FIG. 2, second barrier layer 122a, metal layer 120a and/or first barrier layer 121a may be etched using mask pattern 130 as a mask. According to embodiments, etching may form second barrier layer pattern 122, metal interconnections 120 and/or first barrier layer pattern 121. In embodiments, metal interconnections 120 may be spaced apart from each other, and may be spaced at an interval between approximately 0.11 μm to 0.16 μm.

According to embodiments, first barrier layer pattern 121, metal interconnections 120 and/or second barrier layer pattern 122 may be formed in and/or over lower substrate 110. In embodiments, mask pattern 130 may be formed in and/or over second barrier layer pattern 122 to form first barrier layer pattern 121, metal interconnections 120 and/or second barrier layer pattern 122.

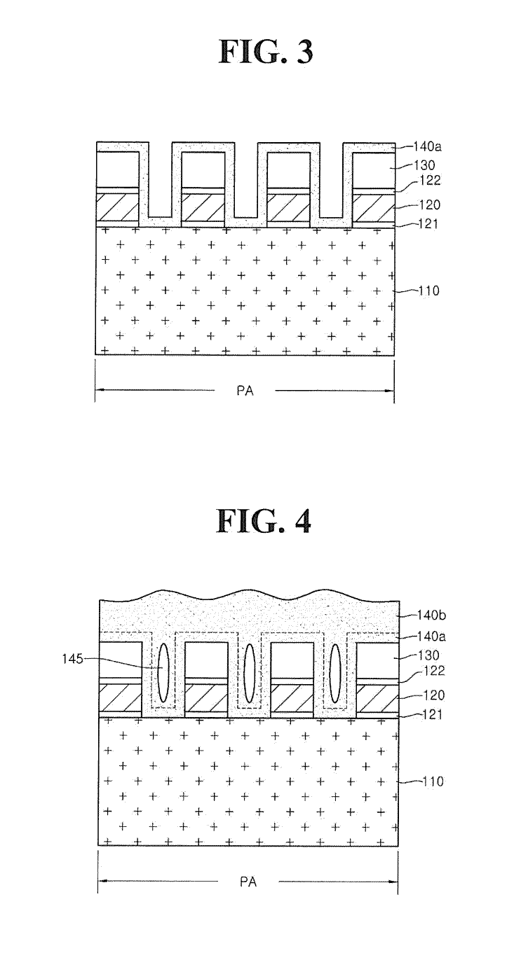

Referring to FIG. 3, first insulating layer 140a may be formed in and/or over a surface of lower substrate 110. In embodiments, first insulating layer 140a may be formed in and/or over an entire surface of lower substrate 110 formed having first barrier layer pattern 121, metal interconnections 120 and/or second barrier layer pattern 122. In embodiments, first insulating layer 140a may be formed through for example a high density plasma chemical vapor deposition (HDP-CVD) scheme.

According to embodiments, first insulating layer 140a may include a silicon oxide layer. In embodiments, first insulating layer 140a may include a undoped silicate glass (USG) layer. In embodiments, a deposition rate of first insulating layer 140a may be between approximately 30 Å/sec to 100 Å/sec. In embodiments, first insulating layer 140a may have a thickness between approximately 200 Å to 1000 Å. In embodiments, similar to a liner oxide layer, first insulating layer 140a may be formed along a concave-convex section which may be defined by metal interconnections 120. In embodiments, first insulating layer 140a may have an interval between approximately 0.063 μm to 0.11 μm between metal interconnections 120.

Referring to FIG. 4, second insulating layer 140b may be formed in and/or over first insulating layer 140a. According to embodiments, second insulating layer 140b may be formed through a plasma enhancement chemical vapor deposition (PE-CVD) scheme. In embodiments, a deposition rate for second insulating layer 140b may be between approximately 200 Å/sec to 500 Å/sec. In embodiments, second insulating layer 140b may have a thickness between approximately 3000 Å to 5000 Å.

According to embodiments, second insulating layer 140b may include substantially similar material as first insulating layer 140a. In embodiments, second insulating layer 140b may include a USG layer. In embodiments, a deposition rate of second insulating layer 140b may be higher relative to a deposition rate of first insulating layer 140a. In embodiments, first insulating layer 140a may be configured as a concave-convex pattern along metal interconnections 120, and second insulating layer 140b may be deposited while filling the concave-convex pattern. In embodiments, second insulating layer 140b may be deposited faster relative to first insulating layer 140a, and an air gap 145 may be formed between metal interconnections 120.

According to embodiments, a height of air gap 145 may be lower relative to a height of metal interconnections 120, but is not limited thereto. In embodiments, a height of air gap 145 may be higher relative to a height of metal interconnections 120, and may depend on an interval of metal interconnections, a deposition rate of an insulating layer and/or a thickness of a first insulating layer that may have been previously formed.

According to embodiments, first insulating layer 140a and second insulating layer 140b may form one interlayer dielectric layer. In embodiments, due to air gap 145 formed in and/or over second insulating layer 140b, the dielectric constant of first insulating layer 140a and second insulating layer 140b may be minimized.

According to embodiments, air gap 145 may be formed between metal interconnections 120 in and/or over a pixel area (PA) of an image sensor. In embodiments, air gap 145 may be formed between metal interconnections 120 in and/or over a pixel area (PA) and a logic area (LA) of a image sensor. In embodiments, a design rule of a pixel area (PA) may be different than a design rule of a logic area LA. In embodiments, when a design rule of a pixel area (PA) is relatively smaller to a design rule of a logic area (LA), air gap 145 may be formed in and/or over a pixel area (PA).

According to embodiments, air gap 145 may be formed taking a deposition rate, design, and/or the purpose into consideration. In embodiments, first insulating layer 140a and second insulating layers 140b may include a tetra ethyl ortho silicate (TEOS) layer, which may have a dielectric constant of approximately 4.4. In embodiments, air gap 145 may be an air layer having a dielectric constant of approximately 1, and the dielectric constant of an interlayer dielectric layer formed may be lowered to between approximately 2.5 to 3.0. In embodiments, when light is incident into a photodiode of a semiconductor substrate by passing through a plurality of interlayer dielectric layers, the light loss may be minimized due to an air gap formed in and/or over interlayer dielectric layers. In embodiments, quantum efficiency may be relatively maximized, for example between approximately 10% to 20%. In embodiments, light efficiency may be maximized. In embodiments, capacitance of an insulating layer may be relatively reduced in a logic area (LA) of an image sensor. In embodiments, device characteristics may be maximized.

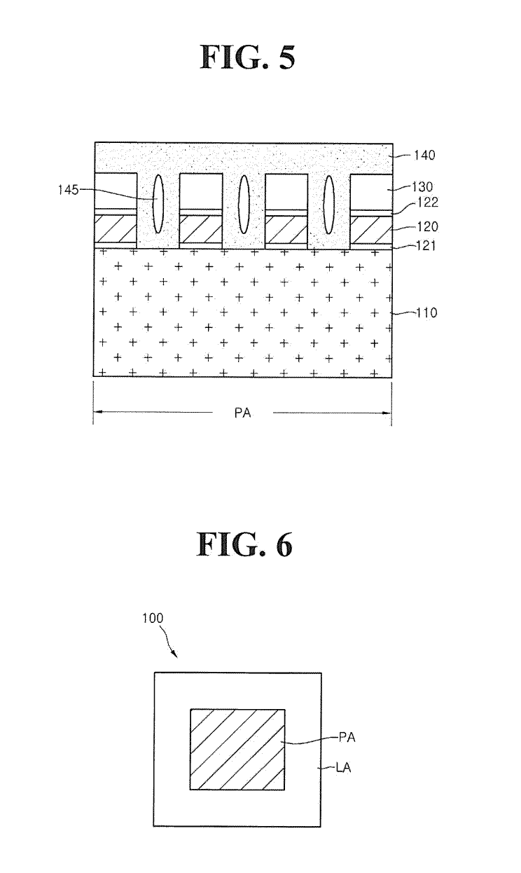

Referring to FIG. 5, atop surface of second insulating layer 140b may be planarized, for example through a polishing process. According to embodiments, interlayer dielectric layer 140 may be formed. In embodiments, interlayer dielectric layer 140 may be a first interlayer dielectric layer that may cover a first metal interconnection in an image sensor, such as image sensor 100. In embodiments, a second metal layer may be formed in and/or over a first interlayer dielectric layer, and a second interlayer dielectric layer may be formed in and/or over a second metal layer which may cover the second metal layer. In embodiments, a plurality of alternating insulating layers and metal interconnections may be formed.

According to embodiments, a pad may be formed in and/or over a final insulating layer. In embodiments, a protective layer may be formed in and/or over a pad, which may cover a pad. In embodiments, a color filter layer and/or a micro-lens may be formed in and/or over a protective layer.

According to embodiments, an HDP-oxide, as a liner, may have maximized gap-fill characteristics and may be formed in and/or over lower substrate 110. In embodiments, lower substrate 110 may be formed including first barrier layer pattern 121, metal interconnection 120 and/or second barrier layer pattern 122. In embodiments, PE-oxide may have a deposition rate higher relative to a deposition rate of an HDP-oxide, and may be deposited in and/or over an HOP-oxide. In embodiments, air gap 145 may intentionally be formed in and/or over a relatively narrow area between metal interconnections 120. In embodiments, the dielectric constant of interlayer dielectric layer 140 may be minimized.

According to the embodiments, air gap 145 may be formed in and/or over interlayer dielectric layer 140, which may be formed in and/or over a photodiode of an image sensor. In embodiments, a transmission efficiency of light incident into a photodiode from a micro-lens may be maximized. In embodiments, light absorption and/or light reflection caused by an insulating layer may be substantially prevented. In embodiments, quantum efficiency may be maximized. In embodiments, light sensitivity may be maximized.

Embodiments relate to an image sensor. Example FIG. 6 illustrates a plan view of an image sensor in accordance with embodiments. Referring to FIG. 6, a pixel array may be formed in and/or over a pixel area (PA) of image sensor 100. According to embodiments, a photodiode and/or a transistor may be formed in and/or over each pixel. In embodiments, various circuits may be mounted in and/or over a LA (logic area). In embodiments, a LA may be located adjacent to a PA. In embodiments, a LA may drive a pixel array. In embodiments, a plurality of transistors may be mounted in and/or over a LA.

According to embodiments, transistors may be formed in and/or over a PA with a design rule of approximately 90 nm. In embodiments, a transistor may be formed in and/or over a LA with a design rule of approximately 110 nm. In embodiments, an air gap may formed in and/or over a interlayer dielectric layer of a PA between metal interconnections as a result of relative differences in design rule.

According to embodiments, an air gap may be formed in and/or over an interlayer dielectric layer of a LA between metal interconnections, and may be formed in addition to an air gap formed in and/or over interlayer dielectric layer of a PA. In embodiments, an air gap formed in and/or over an LA may reduce capacitance between interconnections. In embodiments, device characteristics may be maximized.

According to embodiments, a pixel array may include a transistor and/or a photodiode electrically connected to a photodiode which may be formed in and/or over a semiconductor substrate. In embodiments, a plurality of insulating layer structures and/or interconnection layers may be formed in and/or over a pixel area. In embodiments, a color filter array may be formed in and/or over an insulating layer structure, which may provide for realizing a color image of an image sensor. In embodiments, a planar layer may be formed in and/or over a top surface of a color filter. In embodiments, a photoresist film may be coated in and/or over a top surface of a planar layer. In embodiments, a reflow process may be performed to form a micro-lens which may provide collected light to a pixel array.

According to embodiments, an insulating layer structure may include a plurality of interlayer dielectric layers, in which at least one interlayer dielectric layer may have an air gap between metal interconnections. In embodiments, an insulating layer structure, a color filter layer and/or a micro-lens may be arranged corresponding to a photodiode. In embodiments, light incident through a micro-lens may pass through an insulating layer structure and may be incident into a photodiode. In embodiments, an air gap may be formed in and/or over an insulating layer structure, and light transmittance may be maximized. In embodiments, light efficiency may be maximized.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
metal interconnections formed over a lower substrate;
a hard mask formed over said metal interconnections; and
an insulating layer formed over a surface of said lower substrate,
wherein said insulating layer comprises an air gap between said metal interconnections.

2. The apparatus of claim 1, wherein:
said lower substrate is a semiconductor substrate; and
said insulating layer is formed over an entire surface of said lower substrate.

3. The apparatus of claim 2, wherein said insulating layer comprises a undoped silicate glass layer.

4. The apparatus of claim 2, wherein said lower substrate comprises:
a photodiode formed over said semiconductor substrate by implanting impurities into said semiconductor substrate;
a plurality of transistors formed over said semiconductor substrate; and
a pre-metal dielectric layer covering at least one of said transistors.

5. The apparatus of claim 1, wherein said insulating layer comprises:
a first insulating layer formed over a surface of said lower substrate, wherein said first insulating layer comprises a thickness between approximately 200 Å to 1000 Å and extends along a concave-convex section defined by said metal interconnections and said hard mask; and
a second insulating layer formed over said first insulating layer, wherein said second insulating layer comprises said air gap.

6. The apparatus of claim 1, wherein:
an interval between said metal interconnections is between approximately 0.11 μm to 0.16 μm; and
a gap of said first insulating layer between said metal interconnections is between approximately 0.06 μm to 0.11 μm.

7. A method comprising:
forming a metal layer over a lower substrate;
forming a mask layer over said metal layer;
forming a hard mask;
forming a metal interconnection;
forming a first insulating layer along a concave-convex section over at least one of said hard mask and said metal interconnection; and
forming a second insulating layer over said first insulating layer to form an air gap between said metal interconnection.

8. The method of claim 7, wherein:
forming said hard mark comprises patterning said mask layer;
forming said metal interconnection comprises etching said metal layer using said hard mask; and
wherein said second insulating layer is planarized.

9. The method of claim 8, comprising:
forming a metal interconnection layer and an insulating layer structure over said second insulating layer after planarizing said second insulating layer; and
forming a color filter layer and a micro-lens over said insulating layer structure.

10. The method of claim 7, wherein:
said first insulating layer comprises a thickness between approximately 200 Å to 1000 Å; and
said second insulating layer comprises a thickness between approximately 3000 Å to 5000 Å.

11. The method of claim 7, wherein:
said first insulating layer is formed comprising high density plasma chemical vapor deposition; and
said second insulating layer is formed comprising plasma enhanced chemical vapor deposition.

12. The method of claim 7, wherein:
said metal layer comprises a thickness between approximately 300 Å to 5000 Å; and
said hard mask comprises a thickness between approximately 500 Å to 1200 Å.

13. An apparatus comprising:
a pixel array area comprising photodiodes and transistors formed over a semiconductor substrate;
a logic area comprising a plurality of transistors formed over said semiconductor substrate;
a metal interconnection and an insulating layer structure connected to said transistors and covering said pixel array area and said logic area; and
a color filter layer formed over said pixel array area,
wherein said insulating layer structure of said pixel array area comprises an air gap between said metal interconnection.

14. The apparatus of claim 13, wherein said transistors are aligned over said pixel array area comprising a design rule of approximately 90 nm.

15. The apparatus of claim 13, wherein said transistors are aligned over said logic area comprising a design rule of approximately 110 nm.

16. The apparatus of claim 13, wherein said insulating layer structure comprises:
a first insulating layer formed over an entire surface of said semiconductor substrate along a concave-convex section of said metal interconnection, wherein said first insulating layer comprises a thickness between approximately 200 Å to 1000 Å; and
a second insulating layer formed over said first insulating layer, wherein said second insulating layer comprises said air gap.

17. The apparatus of claim 16, wherein:
an interval between said metal interconnection is between approximately 0.11/cm to 0.16 μm; and
a gap of said first insulating layer between said metal interconnection is between approximately 0.06 μm to 0.11 μm.

18. The apparatus of claim 13, comprising a hard mask to form said metal interconnection.

19. A method comprising:
forming a pixel array area comprising photodiodes and transistors over a semiconductor substrate;
forming a logic area comprising a plurality of transistors over a semiconductor substrate;
forming a pre-metal dielectric layer over an entire surface of said semiconductor substrate such that said pixel array area and said logic area are covered by said pre-metal dielectric layer;
forming a metal interconnection connected to said transistors over said pre-metal dielectric layer;
forming an insulating layer structure comprising an air gap formed between a metal interconnection corresponding to said photodiode; and
forming a color filter layer over said pixel array area.

20. The method of claim 19, wherein forming said metal interconnection connected to the transistors over said pre-metal dielectric comprises:
forming a metal layer over said pre-metal dielectric layer;
forming a mask layer over said metal layer;
forming a hard mask by patterning said mask layer; and
forming said metal interconnection by etching said metal layer using said hard mask.
